(19) United States
(12) Patent Application Publication
(10) Pub. No.: US 2008/0204567 A1
(43) Pub. Date: Aug. 28, 2008

(54) SAMPLE AND HOLD CIRCUITS WITH BUFFER OFFSET REMOVED

(76) Inventor: Weize Xu, Rochester, NY (US)

Correspondence Address: Frank Pincelli;Patent Legal Staff, Eastman Kodak Company, 343 State Street, Rochester, NY, 14650-2201, US

(21) Appl. No.: 11/678,293

(22) Filed: Feb. 23, 2007

(51) Int. Cl. H04N 5/228

(52) U.S. Cl. 348/222.1; 348/E05.031

(57) ABSTRACT

An active pixel image sensor comprising: (a) a pixel array having a plurality of pixels, each pixel comprising: (i) a photosensitive region connected to a charge-to-voltage conversion region; and (ii) an amplifier connected to the charge-to-voltage conversion region; and (b) a sample and hold circuit connected to one or more pixels comprising: (i) two capacitors for receiving and storing a reset signal and an image signal; (ii) two buffer amplifiers for respectively receiving the reset signal and the image signal respectively from the two capacitors; and (iii) a reference generator circuit connected to an input of the buffer amplifiers for removing offset of the buffer amplifier.

### FIELD OF THE INVENTION

The invention relates generally to the field of images and, more particularly, to such image sensors that efficiently remove the buffer offset voltage.

### BACKGROUND OF THE INVENTION

Referring to FIG. 1, there is shown a prior art pixel 10 connected to its respective sample and hold circuit 20. The pixel 10 includes a photosensitive region 30 for collecting charge carriers, preferably electrons, in response to light. A transfer gate 40 transfers the charge from the photosensitive region 30 to a charge-to-voltage conversion region 50, preferably a floating diffusion. A reset transistor 60 resets the floating diffusion 50 to a predetermined voltage level. A pixel amplifier 70, preferably a source follower, amplifies the voltage for input to the column sample and hold circuit 20. A row select transistor 80 selects that particular row for output.

The sample and hold circuit 20 includes two sampling switches 90a and 90b respectively connected to two sample and hold capacitors 100a and 100b for sampling the reset level and image signal level at different times from the amplifier 70 and respectively holding their signals. First, switch 90a is closed and the reset level passes to the sample and hold capacitor 100a, and then switch 90a opens and switch 90b closes, and the image signal level passes to the sample and hold capacitor 100b. Then switch 90b opens and the both signals are respectively held by capacitors 100a and 100b. When this column is addressed, switches 110a and 110b close and the signals are buffered and sent to the correlated double sampling (CDS) amplifier 120. Switch 130 closes and a voltage is created at the node 140 (graphically represented by a dashed line). This voltage is typically the average of the reset voltage and image signal level. This voltage is used as a reference voltage and is sent to the CDS 120 amplifier for offset removal.

Although the presently known and utilized image sensor is satisfactory, it includes drawbacks. The prior art image sensor is time consuming because of the time required to generate and stabilize the reference voltage. In addition, the reference voltage is dependent on the image signal level so this affects the efficiency of the CDS to remove offset.

Consequently, a need exists to overcome the above-described drawbacks.

### SUMMARY OF THE INVENTION

The present invention is directed to overcoming one or more of the problems set forth above. Briefly summarized, according to one aspect of the present invention, the invention resides in an active pixel image sensor comprising: (a) a pixel array having a plurality of pixels, each pixel comprising: (i) a photosensitive region connected to a charge-to-voltage conversion region; and (ii) an amplifier connected to the charge-to-voltage conversion region; and (b) a sample and hold circuit connected to one or more pixels comprising: (i) two capacitors for receiving and storing a reset signal and an image signal; (ii) two buffer amplifiers for respectively receiving the reset signal and the image signal respectively from the two capacitors; and (iii) a reference generator circuit connected to an input of the buffer amplifiers for removing offset of the buffer amplifier.

These and other aspects, objects, features and advantages of the present invention will be more clearly understood and appreciated from a review of the following detailed description of the preferred embodiments and appended claims, and by reference to the accompanying drawings.

### ADVANTAGEOUS EFFECT OF THE INVENTION

The present invention has the following advantage of having high speed circuitry that generates the offset reference voltage and a more efficient offset voltage removal since the reference voltage does not follow the image signal.

### BRIEF DESCRIPTION OF THE DRAWINGS

FIG. 1 is a schematic diagram of a portion of a prior art image sensor and its associated sample and hold circuit;

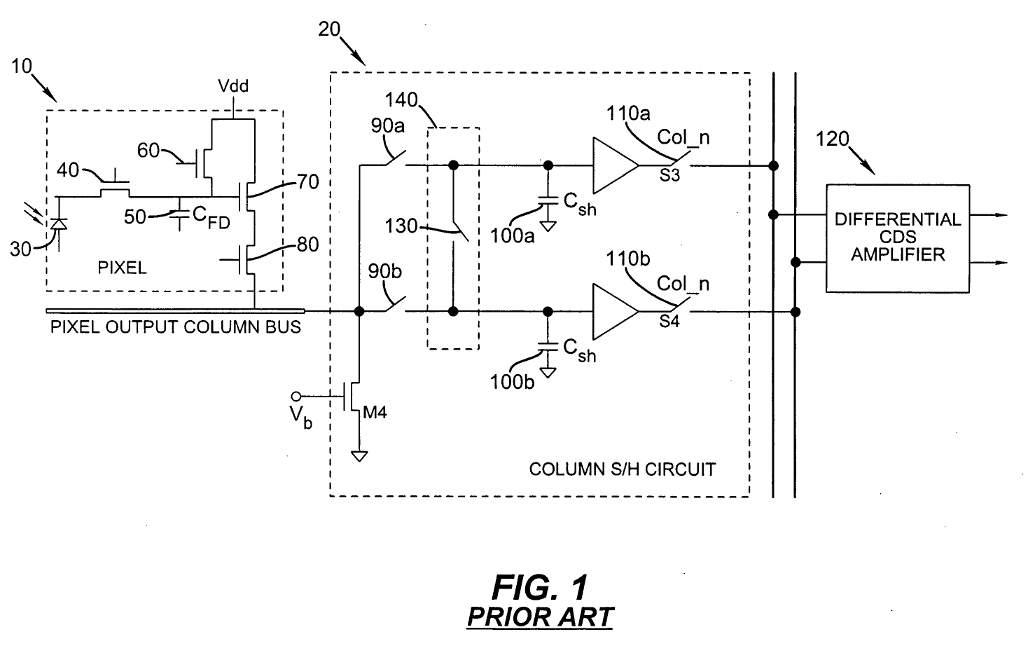

FIG. 2 is a an image sensor of the present invention and its associated sample and hold array; and

FIG. 3 is a pixel of the present invention with its associated sample and hold circuit.

### DETAILED DESCRIPTION OF THE INVENTION

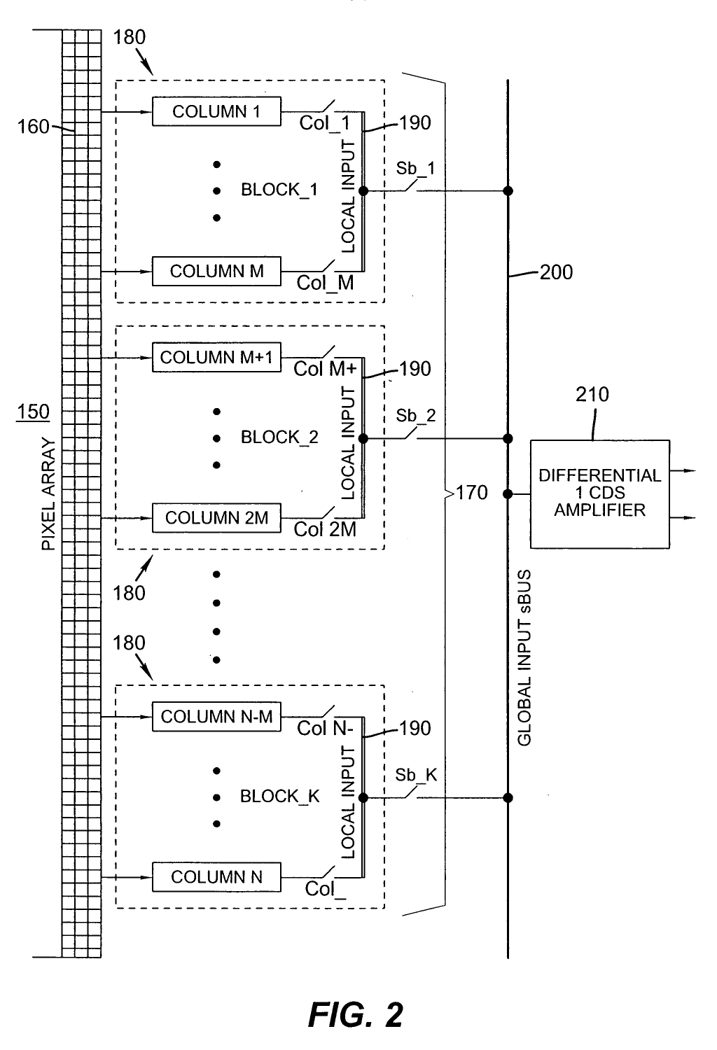

Referring to FIG. 2, there is shown a pixel array 150 having a plurality of pixels 160 electrically connected to a sample and hold array 170 having a plurality of sub-arrays. Each sub-array includes a column sample and hold circuit 180 connected to a local bus 190 which, in turn, is connected to a global bus 200 and eventually to a differential CDS amplifier 210.

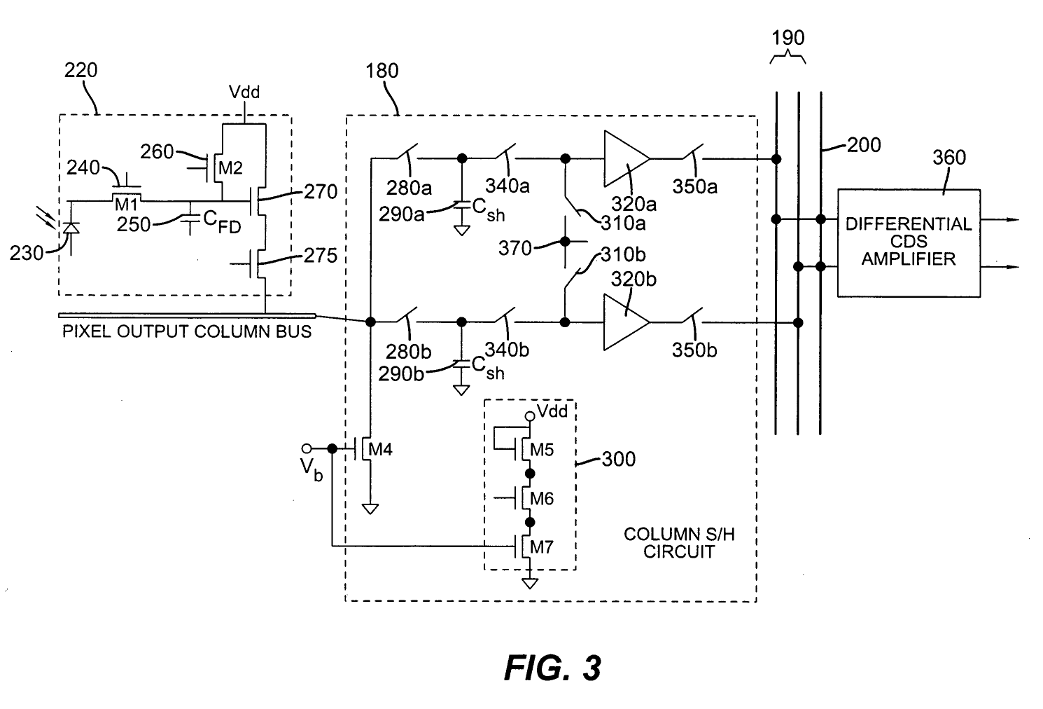

Referring to FIG. 3, there is shown a pixel 220 connected to its respective sample and hold circuit 180. The pixel 220 includes a photosensitive region 230 for collecting charge carriers, preferably electrons, in response to light. A transfer gate 240 transfers the charge from the photosensitive region 230 to a charge-to-voltage conversion region 250, preferably a floating diffusion. A reset transistor 260 resets the floating diffusion 250 to a predetermined voltage level. A pixel amplifier 270, preferably a source follower, amplifies the voltage for input to the column sample and hold circuit 180. A row select transistor 275 selects the particular row for output.

The sample and hold circuit 180 includes two sampling switches 280a and 280b respectively connected to two sample and hold capacitors 290a and 290b for respectively sampling the reset voltage level and the image signal level from the amplifier 270 and holding it temporarily (i.e., until it is addressed). A reference voltage generator 300 is enabled when this particular column is addressed. Two switches 310a and 310b provide an electrical path (when closed) to two buffer amplifiers 320a and 320b for providing the signal from the reference voltage generator 300 removing the amplifier offset voltage. Another two switches 340a and 340b are each connected to an input of a buffer amplifier 320a and 320b. Two enable switches 350a and 350b are enabled for passing the signal onto the local bus 190 and then the global bus 200 and eventually to the differential CDS amplifier 360.

Each reference voltage generator 300 includes three transistors—an amplifier M5 (preferably a source follower), an enable switch M6, and a bias transistor M7. The power supply voltage Vdd is connected to the gate of the amplifier transistor M5, and the bias transistor M7 supplies the bias current for the amplifier M5. Switch M6 enables amplifier M5 and also enables the output of the amplifier M5 to pass to node 370. The reference voltage applied to the node 370 is typically between the reset level and the image signal level. Preferably, the reference voltage is close to, but less than, the reset voltage level.

Describing an exemplary operation of the present invention, the reset transistor 260 is turned on for resetting the floating diffusion 250 to a known level. The switch 280a is turned on for passing the signal from the pixel amplifier 270 to the capacitor 290a for holding the reset level. Then switch 280a is opened and the transfer gate 240 is enabled for transferring the image charge to the floating diffusion 250 where it is converted to a voltage. Switch 280b is turned on for passing the image signal through the pixel amplifier 270 to the capacitor 290b.

This column is enable by closing switches 350a and 350b for permitting the image and reset level to the local bus 190 and then to the global bus 200 and eventually to the differential CDS amplifier 360 where the pixel offset is removed. This signal is then passed to processing circuits (not shown) for well known processing and which will not be described in detail herein. Switches 340a and 340b are opened and switches 310a and 310b are closed for passing the reference voltage from the reference voltage generator 300 to the buffer amplifiers 320a and 320b. These signal are passed to the differential CDS amplifier 360 where the offset of the two amplifiers 320a and 320b are removed.

The invention has been described with reference to a preferred embodiment. However, it will be appreciated that variations and modifications can be effected by a person of ordinary skill in the art without departing from the scope of the invention.

### PARTS LIST

10 pixel
20 sample and hold circuit
30 photosensitive region
40 transfer gate
50 charge-to-voltage conversion region (floating diffusion)
60 reset transistor
70 pixel amplifier (source follower)
80 row select transistor
90a sampling switch
90b sampling switch
100a sample and hold capacitor
100b sample and hold capacitor
110a switch
110b switch
120 correlated double sampling (CDS) amplifier
130 switch
140 node
150 pixel array
160 plurality of pixels
170 sample and hold array
180 sample and hold circuit
190 local bus
200 global bus
210 differential CDS amplifier
220 pixel
230 photosensitive region
240 transfer gate
250 charge-to-voltage conversion region (floating diffusion)
260 reset transistor
270 pixel amplifier (source follower)
275 row select transistor
280a sampling switch
280b sampling switch
290a sample and hold capacitor
290b sample and hold capacitor
300 reference voltage generator
310a switch
310b switch
320a buffer amplifier
320b buffer amplifier
340a switch
340b switch
350a enable switch
350b enable switch
360 differential CDS amplifier
370 node

1. An active pixel image sensor comprising:
(a) a pixel array having a plurality of pixels, each pixel comprising:
(i) a photosensitive region connected to a charge-to-voltage conversion region; and
(ii) an amplifier connected to the charge-to-voltage conversion region; and
(b) a sample and hold circuit connected to one or more pixels comprising:
(i) two capacitors for receiving and storing a reset signal and an image signal;
(ii) two buffer amplifiers for respectively receiving the reset signal and the image signal respectively from the two capacitors; and
(iii) a reference generator circuit connected to an input of the buffer amplifiers for removing offset of the buffer amplifier.

2. The active pixel sensor as in claim 1 further comprising a pair of switches for respectively connecting the reference voltage generator to each buffer amplifier.

3. The active pixel sensor as in claim 1, wherein the reference voltage generator is a level shift voltage generator.

4. The active pixel sensor as in claim 3, wherein the level shift voltage generator includes a source follower amplifier and an enable switch.

5. The active pixel sensor as in claim 4, wherein the source follower amplifier includes one input transistor and one bias transistor.

6. The active pixel sensor as in claim 1, wherein the reference voltage generator includes an amplifier, a bias transistor, and a switch.
